(19) United States
(12) Patent Application Publication
(10) Pub. No.: US 2017/0063368 A1
(43) Pub. Date: Mar. 2, 2017

(54) CALIBRATING FOR ON-RESISTANCE MISMATCH OF DIGITAL-TO-ANALOG CONVERTER (DAC) SWITCHES

(71) Applicant: QUALCOMM INCORPORATED, San Diego, CA (US)

(72) Inventors: Dongyang TANG, San Diego, CA (US); Vijayakumar DHANASEKARAN, San Diego, CA (US)

(21) Appl. No.: 14/835,222

(22) Filed: Aug. 25, 2015

(51) Int. Cl. H03K 17/687; H03M 1/66; H03M 1/10

(52) U.S. Cl. CPC H03K 17/687; H03M 1/1009; H03M 1/66

(57) ABSTRACT

Certain aspects of the present disclosure provide methods and apparatus for setting a voltage level for controlling at least one of a first switch or a second switch, such that an on-resistance of the first switch matches an on-resistance of the second switch. One example circuit generally includes a third switch configured to replicate the first switch and a first cascode device connected in cascode with the third switch; a first amplifier configured to drive the first cascode device; a fourth switch configured to replicate the second switch; a second cascode device connected in cascode with the fourth switch; a second amplifier configured to drive the second cascode device; and a third amplifier configured to compare a voltage at a node coupled to the first and second cascode devices with a reference potential and to control the third switch based on the comparison to set the voltage level.

### TECHNICAL FIELD

Certain aspects of the present disclosure generally relate to electronic circuits and, more particularly, to matching on-resistances of switches.

### BACKGROUND

Digital audio processing may be performed in various devices, such as audio receivers, computers, tablets, smartphones, user terminals, and the like. For digital audio processing, an encoder-decoder (CODEC) may be used to convert analog audio signals to encoded digital signals and vice versa. For example, a CODEC may receive an analog audio signal (e.g., from a microphone), and convert the analog audio signal into a digital signal that can be processed (e.g., digitally filtered) via a digital signal processor (DSP). The CODEC can then convert the processed digital output of the DSP to an analog signal for use by audio speakers, for example, via a digital-to-analog converter (DAC).

One type of DAC that may be employed in a CODEC is a resistive DAC (RDAC). An RDAC may include one or more switches (e.g., transistors), each having a control input that can be driven such that the switch is off/open/inactive (e.g., allowing little to no current to flow) or on/closed/active. During the on state, each switch may have a specific on-resistance, which, in the case of transistors, may depend on a voltage used to drive the control input of the switch.

### SUMMARY

Certain aspects of the present disclosure generally relate to techniques and apparatus for matching on-resistances of switches, such as complementary transistors functioning as switches in a resistive digital-to-analog converter (RDAC) unit element.

Certain aspects of the present disclosure provide a circuit for setting a voltage level for controlling at least one of a first switch or a second switch, such that an on-resistance of the first switch matches an on-resistance of the second switch. The circuit generally includes a third switch configured to replicate the first switch; a first cascode device connected in cascode with the third switch; a first amplifier configured to drive the first cascode device; a fourth switch configured to replicate the second switch; a second cascode device connected in cascode with the fourth switch; a second amplifier configured to drive the second cascode device; and a third amplifier configured to compare a voltage at a node coupled to the first and second cascode devices with a reference potential (e.g., electrical ground) and to control the third switch based on the comparison to set the voltage level.

In certain aspects, the third switch is coupled to a first voltage rail, and the fourth switch is coupled to a second voltage rail. In certain aspects, an input of the first amplifier is coupled to the third switch and to the first cascode device, and another input of the first amplifier is biased with a first bias voltage, offset from the first voltage rail by an offset voltage magnitude. In certain aspects, an input of the second amplifier is coupled to the fourth switch and to the second cascode device, and another input of the second amplifier is biased with a second bias voltage, offset from the second voltage rail by the same offset voltage magnitude. In certain aspects, the first amplifier is configured to drive the first cascode device such that a voltage at the input of the first amplifier substantially equals the first bias voltage and such that a potential across the third switch substantially equals the offset voltage magnitude. In certain aspects, the second amplifier is configured to drive the second cascode device such that a voltage at the input of the second amplifier substantially equals the second bias voltage and such that a potential across the fourth switch substantially equals the offset voltage magnitude. In certain aspects, the third amplifier is configured to drive the third switch such that an on-resistance of the third switch matches an on-resistance of the fourth switch. In certain aspects, the first voltage rail is configured to set the on-resistance of the fourth switch.

In certain aspects, the first voltage rail has a higher voltage than the second voltage rail. In this case, the third switch may comprise a p-channel metal-oxide semiconductor (PMOS) transistor, the fourth switch may comprise an n-channel metal-oxide semiconductor (NMOS) transistor, the first cascode device may comprise a PMOS transistor, and the second cascode device may comprise an NMOS transistor.

In other aspects, the second voltage rail has a higher voltage than the first voltage rail. In this case, the third switch may comprise an NMOS transistor, the fourth switch may comprise a PMOS transistor, the first cascode device may comprise an NMOS transistor, and the second cascode device may comprise a PMOS transistor.

In certain aspects, at least one of the first amplifier or the second amplifier comprises a chopper-stabilized amplifier.

In certain aspects, at least one of the first amplifier or the second amplifier has an input offset voltage parameter of at most ±100 μV.

In certain aspects, the third amplifier may be configured to control the third switch such that the voltage at the node equals the reference potential.

In certain aspects, the first switch and the second switch are part of a unit element in an RDAC.

Certain aspects of the present disclosure provide a method for setting a voltage level for controlling at least one of a first switch or a second switch, such that an on-resistance of the first switch matches an on-resistance of the second switch. The method generally includes establishing a voltage magnitude across a third switch configured to replicate the first switch; establishing the same voltage magnitude across a fourth switch configured to replicate the second switch; setting an on-resistance of the fourth switch based on the voltage magnitude across the fourth switch; comparing a voltage at a node between the third switch and the fourth switch with a reference potential; and controlling the third switch based on the comparison such that an on-resistance of the third switch matches the on-resistance of the fourth switch, wherein an input of the third switch is configured to set the voltage level.

Certain aspects of the present disclosure provide an apparatus for setting a voltage level for controlling at least one of a first means for switching or a second means for switching, such that an on-resistance of the first means for switching matches an on-resistance of the second means for switching. The apparatus generally includes means for establishing a voltage magnitude across a third means for switching configured to replicate the first means for switching; means for establishing the same voltage magnitude across a fourth means for switching configured to replicate the second means for switching; means for setting an on-resistance of the fourth means for switching based on the voltage magnitude across the fourth means for switching; means for comparing a voltage at a node between the third means for switching and the fourth means for switching with a reference potential; and means for controlling the third means for switching based on an output of the means for comparing such that an on-resistance of the third means for switching matches the on-resistance of the fourth means for switching, wherein an input of the third means for switching is configured to set the voltage level.

### BRIEF DESCRIPTION OF THE DRAWINGS

So that the manner in which the above-recited features of the present disclosure can be understood in detail, a more particular description, briefly summarized above, may be had by reference to aspects, some of which are illustrated in the appended drawings. It is to be noted, however, that the appended drawings illustrate only certain typical aspects of this disclosure and are therefore not to be considered limiting of its scope, for the description may admit to other equally effective aspects.

FIG. 1 is a diagram of an example encoder-decoder (CODEC), in accordance with certain aspects of the present disclosure.

FIG. 2 is a diagram of an example calibration circuit for calibrating a p-channel metal-oxide-semiconductor (PMOS) transistor of a resistive digital-to-analog converter (RDAC) unit element, in accordance with certain aspects of the present disclosure.

FIG. 3 is a diagram of an example calibration circuit for calibrating an n-channel metal-oxide-semiconductor (NMOS) transistor of an RDAC unit element, in accordance with certain aspects of the present disclosure.

FIG. 4 is a flow diagram of example operations for setting a voltage level for controlling at least one of a first switch or a second switch, such that an on-resistance of the first switch matches an on-resistance of the second switch, in accordance with certain aspects of the present disclosure.

### DETAILED DESCRIPTION

Various aspects of the present disclosure are described below. It should be apparent that the teachings herein may be embodied in a wide variety of forms and that any specific structure, function, or both being disclosed herein is merely representative. Based on the teachings herein, one skilled in the art should appreciate that an aspect disclosed herein may be implemented independently of any other aspects and that two or more of these aspects may be combined in various ways. For example, an apparatus may be implemented or a method may be practiced using any number of the aspects set forth herein. In addition, such an apparatus may be implemented or such a method may be practiced using other structure, functionality, or structure and functionality in addition to or other than one or more of the aspects set forth herein. Furthermore, an aspect may comprise at least one element of a claim.

The word “exemplary” is used herein to mean “serving as an example, instance, or illustration.” Any aspect described herein as “exemplary” is not necessarily to be construed as preferred or advantageous over other aspects.

### Example Matching of Switch on-Resistances

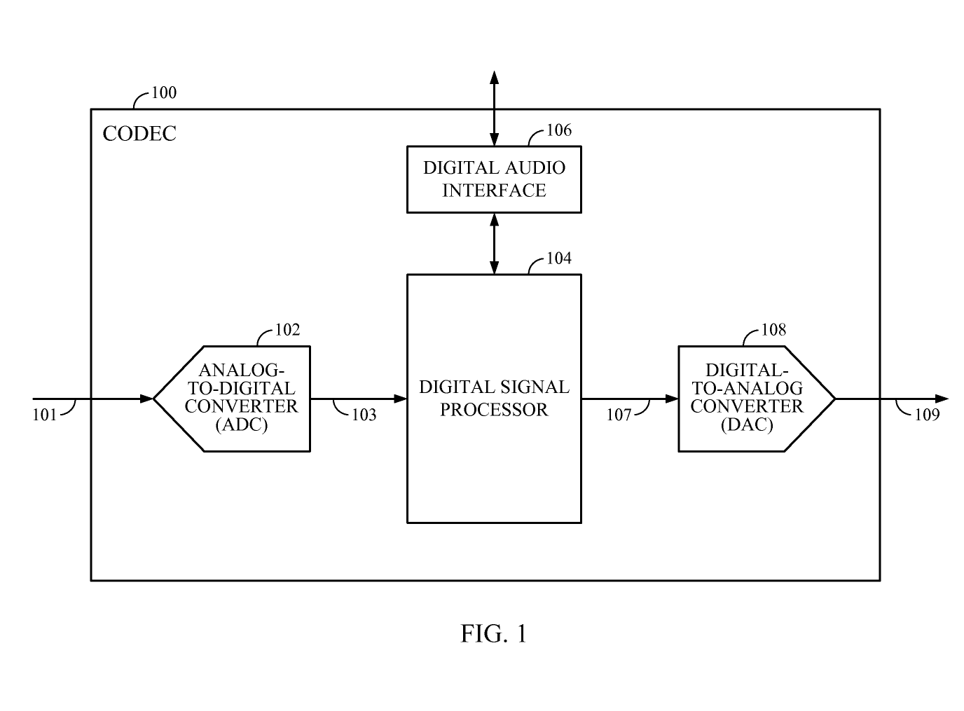

FIG. 1 illustrates an example encoder/decoder (CODEC) 100, according to certain aspects of the present disclosure. The CODEC 100 may receive an analog signal 101 and convert the analog signal into a digital signal 103 via an analog-to-digital converter (ADC) 102. For example, the analog signal 101 input to the ADC 102 may include an input from a microphone. The converted digital signal 103 may be sent to a digital signal processor (DSP) 104, where the DSP may process the digital signal. For example, the DSP 104 may be used for filtering, decimation, adaptive predictive coding, interpolation, or mixing the digital signal 103, to name a few. As used herein, the DSP 104 may include a processing system, which may include one or more processors, each having one or more cores. The DSP 104 may also receive signals for processing from one or more digital components, such as a digital microphone or a memory, via a digital audio interface 106, for example. The CODEC 100 also includes a digital-to-analog converter (DAC) 108, used to convert the processed digital signals 107 from the DSP 104 to analog signals 109, which may be sent to one or more analog components (e.g., speakers).

In certain aspects, the DAC 108 may be a resistive DAC (RDAC). An RDAC may include a resistor ladder circuit that receives a series of inputs corresponding to bit values of the digital signals 107. The resistor ladder circuit may provide a specific analog output based on the series of inputs, which may be buffered and used as the analog output of the RDAC.

The DAC 108 may be powered via differential power supply rails having a positive voltage rail (Vrefp) and a negative voltage rail (Vrefn). For example, Vrefp may be set to +1.5 V, and Vrefn may be set to −1.5 V. The DAC 108 may include push-pull circuitry (in each RDAC unit element) configured to provide an output (e.g., to be input to the resistor ladder circuit) based on Vrefp or Vrefn according to the digital signals 107 input from the DSP 104. That is, depending on the digital input, a p-channel metal-oxide semiconductor (PMOS) transistor may connect a node of the RDAC unit element to Vrefp, or an n-channel metal-oxide semiconductor (NMOS) transistor may connect the node of the RDAC unit element to Vrefn. The node of the RDAC unit element may be connected with a specific resistor (Rn) for that particular element, and the other end of the specific resistance may be connected to other resistors of other RDAC unit elements, such that the output currents of the RDAC unit elements may be summed. An RDAC unit element may exist for each bit of the RDAC. For example, for a sixteen-bit RDAC, the RDAC may include sixteen RDAC unit elements, one for each bit.

If the on-resistances of the PMOS and NMOS transistors are not matched, a change in resistance (ΔR) may be seen at the output of the RDAC unit element when the output transitions between Vrefp and Vrefn. This ΔR may cause an undesired harmonic which may degrade total harmonic distortion (THD). Therefore, what is needed are apparatus and techniques to compensate, or at least adjust, for the on-resistance mismatch of the PMOS and NMOS transistors in an RDAC unit element in order to decrease THD.

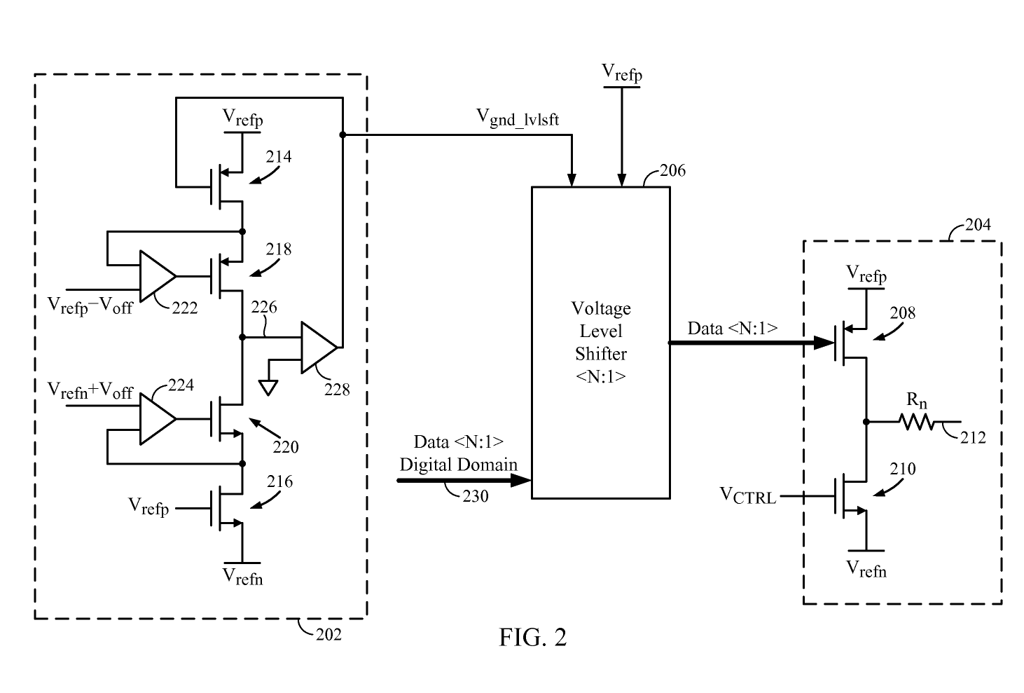

FIG. 2 illustrates a calibration circuit 202 coupled with an RDAC unit element 204 through a level shifter 206, according to certain aspects of the present disclosure. As presented above, the RDAC unit element 204 may include a PMOS transistor 208 connected in cascode with an NMOS transistor 210. A mismatch between the on-resistances of the PMOS and NMOS transistors 208, 210 may be compensated for by level shifting a voltage of a control input to a gate terminal of the PMOS transistor 208. That is, the calibration circuit 202 may establish a voltage (Vgnd_lvlsft) used to control the PMOS transistor 208, such that the on-resistance of the PMOS transistor 208 matches the on-resistance of the NMOS transistor 210 during operation of the RDAC unit element 204.

The calibration circuit 202 may include a PMOS transistor 214 and an NMOS transistor 216, which are replicas of the PMOS and NMOS transistors 208, 210, respectively, of the RDAC unit element 204. For example, the replica PMOS and NMOS transistors 214, 216 may have similar dimensions, channel sizes, and doping as the PMOS and NMOS transistors 208, 210, respectively. Thus, any on-resistance mismatch between the PMOS and NMOS transistors 208, 210 may also exist between the replica PMOS and NMOS transistors 214, 216. As illustrated, the replica PMOS transistor 214 may be connected to another PMOS transistor 218, which is connected in cascode with an NMOS transistor 220 connected in cascode with the replica NMOS transistor 216. The PMOS and NMOS transistors 218, 220 in the calibration circuit 202 may not be replicas of the PMOS and NMOS transistors 208, 210 of the RDAC unit element 204, but can be.

A gate of the PMOS transistor 218 may be coupled with an output of an amplifier 222. As illustrated, the positive input of the amplifier 222 may be set to Vrefp−Voff, where Voff is a desired offset voltage (e.g., 15 mV or 1% of Vrefp) used to set the drain-to-source voltage (Vds) across the replica transistors 214, 216, as described below. The negative input of the amplifier 222 may be used to provide feedback to the amplifier 222 from the drain of the replica PMOS transistor 214 (e.g., coupled to the source of the PMOS transistor 218). Thus, the amplifier 222 may drive the gate of the PMOS transistor 218 such that the voltage at the drain of the replica PMOS transistor 214 is set to approximately Vrefp−Voff (e.g., within the offset voltage capabilities of the amplifier 222). Similarly, the positive input of another amplifier 224 may be set to the negative supply rail plus the same offset voltage (i.e., Vrefn+Voff). The negative input of the amplifier 224 may be used to provide feedback to the amplifier 224 from the drain of the replica NMOS transistor 216 (e.g., coupled to the source of the NMOS transistor 220). Thus, the amplifier 224 may drive the gate of the NMOS transistor 220 such that a drain voltage of the replica NMOS transistor 216 is set to approximately Vrefn+Voff (e.g., within the offset voltage capabilities of the amplifier 224, which may be the same as that for the amplifier 222). Therefore, the Vds of the replica transistors 214, 216 is set to the same voltage magnitude (Voff), or at least nearly the same, depending on the actual offset voltages of the amplifiers 222, 224. In certain aspects, Voff may be selected based on the Vds of the transistors 208, 210, taking into consideration the input offset voltage specifications of (and the potential mismatch between) the amplifiers 222, 224.

As illustrated in FIG. 2 a gate of the replica NMOS transistor 216 is connected with Vrefp to establish the drain-to-source current (Ids) for the calibration circuit 202. For certain aspects, a voltage at node 226 between the PMOS and NMOS transistors 218, 220 may be compared to a reference potential (e.g., electrical ground at 0 V) via an amplifier 228, the output of which provides a voltage level (Vgnd_lvlsft) for the voltage level shifter 206, as well as the drive for the gate of the replica PMOS transistor 214. The amplifier 228 may be configured to compare the voltage at the node 226, input to a first input terminal of the amplifier 228, with the reference potential input to a second input terminal of the amplifier 228. Thus, the amplifier 228 may drive the gate of the replica PMOS transistor 214 such that the voltage at the node 226 is equal to the reference potential.

Moreover, since current does not flow into the input terminals of the amplifier 228, the same current (the Ids of the replica NMOS transistor 216) flows from Vrefp through the replica transistors 214, 216, as well as through the cascode transistors 218, 220 to the Vrefn. The amplifiers 222, 224 are configured to drive the gates of their respective transistors 218, 220 in an effort to maintain their respective feedback voltages at the negative inputs equal to their respective biases at their positive inputs.

As illustrated in FIG. 2, the voltage at node 226 is compared to a reference potential via the amplifier 228, the output of which drives the gate of the replica PMOS transistor 214. Thus, the amplifier 228 adjusts the voltage at the gate of the replica transistor 214 in an effort to match the voltage at node 226 with the reference potential. Therefore, any mismatch in the on-resistances of the replica transistors 214, 216 is reflected in a voltage at the output of the amplifier 228. That is, the amplifier 228 adjusts the gate voltage of transistor 214, thereby effectively adjusting the on-resistance of the transistor 214 (since Vds and Ids for the transistor 214 are fixed). The voltage at the output of the amplifier 228 is therefore adjusted such that a steady state for the calibration circuit 202 is reached where the on-resistance of the replica PMOS transistor 214 matches the on-resistance of the replica NMOS transistor 216. For example, the on-resistances of the replica transistors 214, 216 may be matched such that a difference between the on-resistances of the transistors 214, 216 is less than about 1Ω.

The steady-state voltage at the output of the amplifier 228 is provided to the voltage level shifter 206 as Vgnd_lvlsft and used to level shift a bit of an N-bit digital data stream 230. That is, the voltage level shifter 206 is configured to level shift the input digital data stream 230 between Vrefp and Vgnd_lvlsft. The level-shifted output of the level shifter 206 is used to control the PMOS transistor 208, thus, also adjusting the on-resistance of the transistor 208 to match the on-resistance of the NMOS transistor 210. For example, based on a digital input to the level shifter 206, the level shifter may drive the gate of the PMOS transistor 208 to Vgnd_lvlsft (rather than to Vrefn) such that the PMOS transistor 208 conducts current through element resistance Rn to the output node 212 of the RDAC unit element 204. As a result of this level shifting set by the calibration circuit 202, the on-resistance of the PMOS transistor 208 is adjusted to match the on-resistance of the NMOS transistor 210.

In contrast, the gate of the NMOS transistor 210 may be controlled by a different control voltage (labeled “Vctrl”), based on the digital data stream 230. Instead of changing between binary voltage levels Vrefp and Vgnd_lvlsft (as is the case for the gate of the PMOS transistor 208), Vctrl may change between binary voltage levels Vrefp and Vrefn. For example, based on the digital data stream 230, when the gate of the PMOS transistor 208 is driven to Vgnd_lvlsft, the gate of the NMOS transistor 210 may be driven to Vrefn such that little to no current would be conducted from drain to source of the NMOS transistor 210.

As described above, the RDAC unit element 204 may be part of an array of RDAC unit elements, one for each bit of the digital word supplied to the RDAC. The on-resistance of switches in each of the RDAC unit elements may be matched in a similar manner. For example, the calibration circuit 202 may be used to match the on-resistance of switches in one or more RDAC unit elements of the array, or the on-resistance of switches in each RDAC unit element of the array may be matched using a designated calibration circuit similar to the calibration circuit 202.

While examples provided herein have described matching on-resistances of switches of an RDAC to facilitate understanding, a person having ordinary skill in the art will understand that the calibration circuit 202 may be used to match the on-resistance of switches used in other applications.

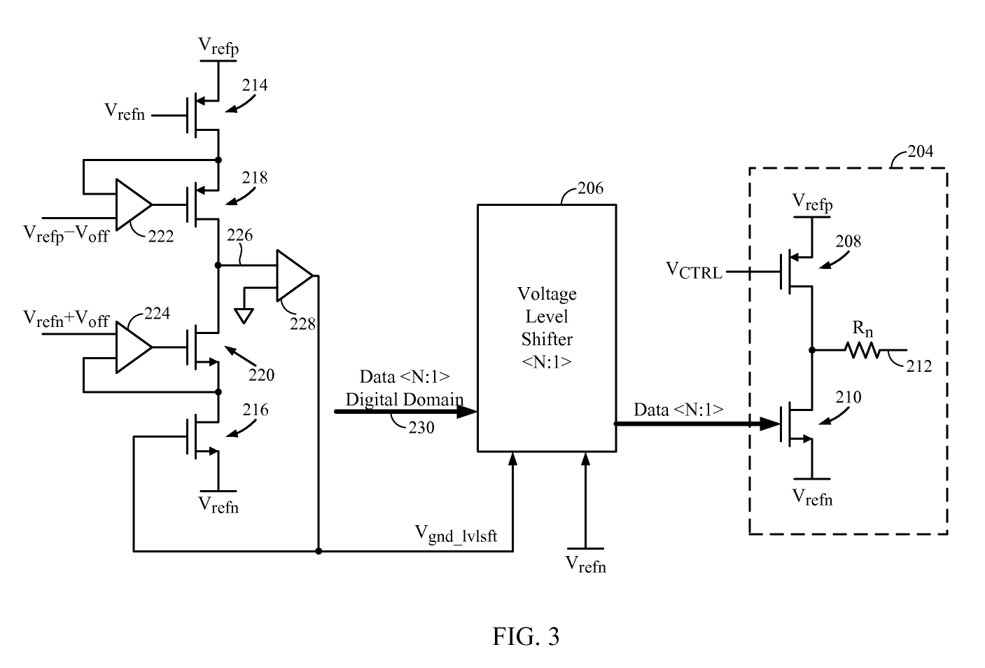

FIG. 3 illustrates a variation of the calibration circuit 202 where the digital input to the NMOS transistor 210 is level shifted, as opposed to the PMOS transistor 208 as in FIG. 2, in accordance with certain aspects of the present disclosure. As illustrated in FIG. 3, a gate of the replica PMOS transistor 214 is controlled by Vrefn to establish the Ids for the calibration circuit. The output of the amplifier 228 is used to drive a gate of the replica NMOS transistor 216, such that a steady state is reached where the on-resistance of the replica PMOS transistor 214 matches the on-resistance of the replica NMOS transistor 216. The output of the amplifier 228 is also used to level shift a digital data stream 230 for controlling the gate of the NMOS transistor 210 (as opposed to the gate of the PMOS transistor 208 as in FIG. 2). In this manner, the inputs to the RDAC unit element 204 drive the transistors 208, 210 with matched on-resistances. In this case, the gate of the NMOS transistor 210 is controlled by the voltage level shifter 206 to change between binary voltage levels Vgnd_lvlsft and Vrefn. In contrast, Vctrl (the control for the gate of the PMOS transistor 208) may change between binary voltage levels Vrefp and Vrefn. For example, based on the digital data stream 230, when the gate of the NMOS transistor 210 is driven to Vgnd_lvlsft, the gate of the PMOS transistor 208 may be driven to Vrefp such that little to no current would be conducted from drain to source of the PMOS transistor 208.

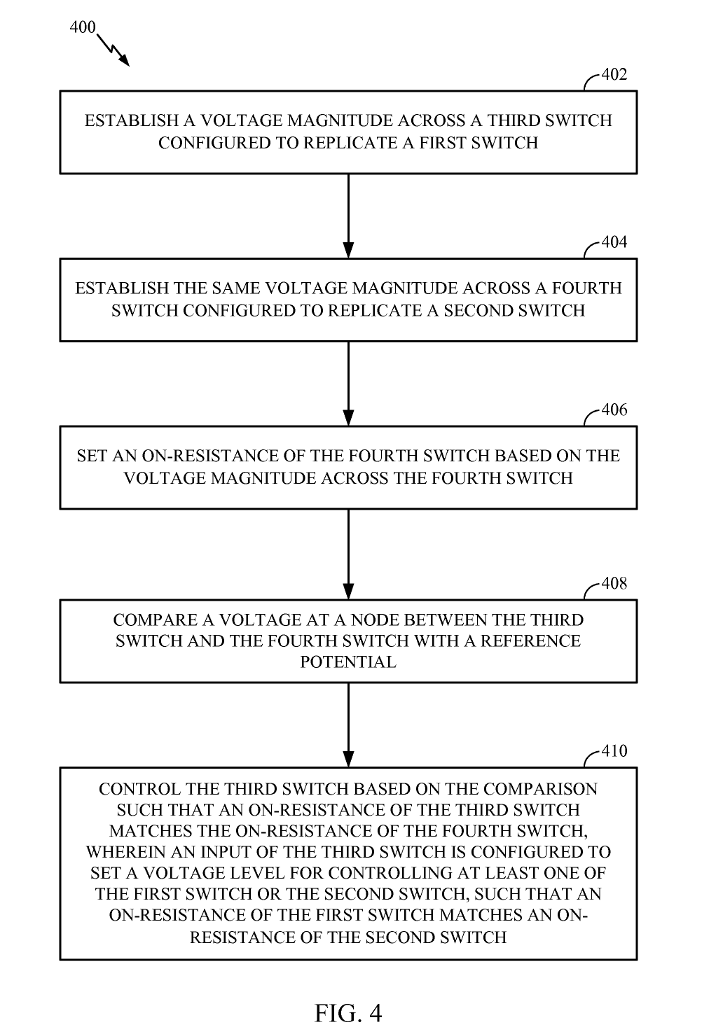

FIG. 4 is a flow diagram of example operations 400 for setting a voltage level for controlling at least one of a first switch or a second switch, such that an on-resistance of the first switch matches an on-resistance of the second switch, in accordance with certain aspects of the present disclosure. The operations 400 may be performed, for example, by a circuit, such as the calibration circuit 202 illustrated in FIG. 2.

The operations 400 may begin, at block 402, with the circuit establishing a voltage magnitude (e.g., magnitude of Voff) across a third switch (e.g., replica PMOS transistor 214 in FIG. 2 or replica NMOS transistor 216 in FIG. 3) configured to replicate the first switch (e.g., PMOS transistor 208 in FIG. 2 or NMOS transistor 210 in FIG. 3). At block 404, the circuit may establish the same voltage magnitude across a fourth switch (e.g., replica NMOS transistor 216 in FIG. 2 or replica PMOS transistor 214 in FIG. 3) configured to replicate the second switch (e.g., NMOS transistor 210 in FIG. 2 or PMOS transistor 208 in FIG. 3). At block 406, the circuit may set an on-resistance of the fourth switch based on the voltage magnitude across the fourth switch. For example, the on-resistance of the fourth switch may be a function of the voltage across the switch (e.g., Vds) and the control input (e.g., the gate-to-source voltage (Vgs)) used to control operation of the switch. At block 408, the circuit may compare a voltage at a node (e.g., node 226) between the third switch and the fourth switch with a reference potential. At block 410, the circuit may control the third switch based on the comparison such that an on-resistance of the third switch matches the on-resistance of the fourth switch, wherein an input (e.g., the gate voltage) of the third switch is configured to set the voltage level (e.g., Vgnd_lvlsft).

According to certain aspects, the third switch is coupled to a first voltage rail (e.g., Vrefp in FIG. 2 or Vrefn in FIG. 3), and the fourth switch is coupled to a second voltage rail (e.g., Vrefn in FIG. 2 or Vrefp in FIG. 3). In certain aspects, the setting at block 406 involves biasing the fourth switch with the first voltage rail. In certain aspects, establishing the voltage magnitude across the third switch at block 402 entails driving a first cascode device (e.g., PMOS transistor 218 in FIG. 2 or NMOS transistor 220 in FIG. 3) with a first amplifier (e.g., amplifier 222 in FIG. 2 or amplifier 224 in FIG. 3), wherein the first cascode device is connected in cascode with the third switch; and biasing an input (e.g., the positive input) of the first amplifier with a first bias voltage (e.g., Vrefp−Voff in FIG. 2 or Vrefn+Voff in FIG. 3), offset from the first voltage rail by the voltage magnitude. In certain aspects, another input (e.g., the negative input) of the first amplifier is coupled to the third switch and to the first cascode device, and the first cascode device is driven such that a voltage at the other input of the first amplifier substantially equals (e.g., within the voltage offset parameter of the first amplifier, which may be about ±100 μV in certain aspects) the first bias voltage. In certain aspects, establishing the same voltage magnitude across the fourth switch at block 404 includes driving a second cascode device (e.g., NMOS transistor 220 in FIG. 2 or PMOS transistor 218 in FIG. 3) with a second amplifier (e.g., amplifier 224 in FIG. 2 or amplifier 222 in FIG. 3), wherein the second cascode device is connected in cascode with the fourth switch; and biasing an input (e.g., the positive input) of the second amplifier with a second bias voltage (e.g., Vrefn+Voff in FIG. 2 or Vrefp−Voff in FIG. 3), offset from the second voltage rail by the same voltage magnitude. In certain aspects, another input (e.g., the negative input) of the second amplifier is coupled to the fourth switch and to the second cascode device, and the second cascode device is driven such that a voltage at the other input of the second amplifier substantially equals (e.g., within the voltage offset parameter of the second amplifier) the second bias voltage.

In certain aspects (as illustrated in FIG. 2 for example), the first voltage rail has a higher voltage than the second voltage rail. In this case, the third switch may comprise a PMOS transistor (e.g., replica PMOS transistor 214), and the fourth switch may comprise an NMOS transistor (e.g., replica NMOS transistor 216). The first cascode device may comprise a PMOS transistor (e.g., PMOS transistor 218), and the second cascode device may comprise an NMOS transistor (e.g., NMOS transistor 220).

In other aspects (as illustrated in FIG. 3 for example), the second voltage rail has a higher voltage than the first voltage rail. In this case, the third switch may comprise an NMOS transistor (e.g., replica NMOS transistor 216), and the fourth switch may comprise a PMOS transistor (e.g., replica PMOS transistor 214). The first cascode device may comprise an NMOS transistor (e.g., NMOS transistor 220), and the second cascode device may comprise a PMOS transistor (e.g., PMOS transistor 218).

In certain aspects, the comparing at block 408 is performed via an amplifier (e.g., amplifier 228 as illustrated in FIGS. 2 and 3), and the controlling at block 410 involves driving the third switch with the amplifier. In this case, an output of the amplifier may be coupled to the input of the third switch.

The various operations or methods described above may be performed by any suitable means capable of performing the corresponding functions. The means may include various hardware and/or software component(s) and/or module(s), including, but not limited to a circuit, an application specific integrated circuit (ASIC), or processor. Generally, where there are operations illustrated in figures, those operations may have corresponding counterpart means-plus-function components with similar numbering.

Means for establishing a voltage magnitude or means for driving may comprise an amplifier (e.g., amplifier 222 or 224 as illustrated in FIGS. 2 and 3) and a transistor (e.g., transistor 218 or 220 as shown in FIGS. 2 and 3). Means for setting an on-resistance or means for biasing may comprise a power supply rail generated by a voltage source (e.g., Vrefp in FIG. 2 or Vrefn as depicted in FIG. 3), a transistor (e.g., replica NMOS transistor 216 in FIG. 2 or replica PMOS transistor 214 in FIG. 3), and/or a voltage reference (not shown). Means for comparing may comprise an amplifier (e.g., amplifier 228 as shown in FIG. 2). Means for controlling may comprise a voltage at a node, which may be generated via at least one transistor (e.g., transistors 218 and 220 of FIG. 2) and/or an amplifier such as the amplifier 228 of FIG. 2. Means for switching may comprise any suitable apparatus capable of functioning as a switch, such as a transistor (e.g., transistors 214, 216 in FIG. 2). Means for providing power may comprise a power supply rail generated by a voltage source (e.g., Vrefp in FIG. 2 or Vrefn as depicted in FIG. 3).

As used herein, the term “determining” encompasses a wide variety of actions. For example, “determining” may include calculating, computing, processing, deriving, investigating, looking up (e.g., looking up in a table, a database or another data structure), ascertaining and the like. Also, “determining” may include receiving (e.g., receiving information), accessing (e.g., accessing data in a memory) and the like. Also, “determining” may include resolving, selecting, choosing, establishing and the like.

As used herein, a phrase referring to “at least one of” a list of items refers to any combination of those items, including single members. As an example, “at least one of: a, b, or c” is intended to cover a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, and c-c-c or any other ordering of a, b, and c).

The various illustrative logical blocks, modules and circuits described in connection with the present disclosure may be implemented or performed with a general purpose processor, a digital signal processor (DSP), an application specific integrated circuit (ASIC), a field programmable gate array (FPGA) or other programmable logic device (PLD), discrete gate or transistor logic, discrete hardware components, or any combination thereof designed to perform the functions described herein. A general-purpose processor may be a microprocessor, but in the alternative, the processor may be any commercially available processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration.

The methods disclosed herein comprise one or more steps or actions for achieving the described method. The method steps and/or actions may be interchanged with one another without departing from the scope of the claims. In other words, unless a specific order of steps or actions is specified, the order and/or use of specific steps and/or actions may be modified without departing from the scope of the claims.

The functions described may be implemented in hardware, software, firmware, or any combination thereof. If implemented in hardware, an example hardware configuration may comprise a processing system in a wireless node. The processing system may be implemented with a bus architecture. The bus may include any number of interconnecting buses and bridges depending on the specific application of the processing system and the overall design constraints. The bus may link together various circuits including a processor, machine-readable media, and a bus interface. The bus interface may be used to connect a network adapter, among other things, to the processing system via the bus. The network adapter may be used to implement the signal processing functions of the physical (PHY) layer. In the case of a user terminal, a user interface (e.g., keypad, display, mouse, joystick, etc.) may also be connected to the bus. The bus may also link various other circuits such as timing sources, peripherals, voltage regulators, power management circuits, and the like, which are well known in the art, and therefore, will not be described any further.

The processing system may be configured as a general-purpose processing system with one or more microprocessors providing the processor functionality and external memory providing at least a portion of the machine-readable media, all linked together with other supporting circuitry through an external bus architecture. Alternatively, the processing system may be implemented with an ASIC with the processor, the bus interface, the user interface in the case of an access terminal), supporting circuitry, and at least a portion of the machine-readable media integrated into a single chip, or with one or more FPGAs, PLDs, controllers, state machines, gated logic, discrete hardware components, or any other suitable circuitry, or any combination of circuits that can perform the various functionality described throughout this disclosure. Those skilled in the art will recognize how best to implement the described functionality for the processing system depending on the particular application and the overall design constraints imposed on the overall system.

It is to be understood that the claims are not limited to the precise configuration and components illustrated above. Various modifications, changes and variations may be made in the arrangement, operation and details of the methods and apparatus described above without departing from the scope of the claims.

What is claimed is:

1. A circuit for setting a voltage level for controlling at least one of a first switch or a second switch, such that an on-resistance of the first switch matches an on-resistance of the second switch, the circuit comprising:
a third switch configured to replicate the first switch;
a first cascode device connected in cascode with the third switch;
a first amplifier configured to drive the first cascode device;
a fourth switch configured to replicate the second switch;
a second cascode device connected in cascode with the fourth switch;
a second amplifier configured to drive the second cascode device; and
a third amplifier configured to:
compare a voltage at a node coupled to the first and second cascode devices with a reference potential; and
control the third switch based on the comparison to set the voltage level.

2. The circuit of claim 1, wherein the third switch is coupled to a first voltage rail and wherein the fourth switch is coupled to a second voltage rail.

3. The circuit of claim 2, wherein:
an input of the first amplifier is coupled to the third switch and to the first cascode device; and
another input of the first amplifier is biased with a first bias voltage, offset from the first voltage rail by an offset voltage magnitude.

4. The circuit of claim 3, wherein:
an input of the second amplifier is coupled to the fourth switch and to the second cascode device; and
another input of the second amplifier is biased with a second bias voltage, offset from the second voltage rail by the same offset voltage magnitude.

5. The circuit of claim 4, wherein:
the first amplifier is configured to drive the first cascode device such that a voltage at the input of the first amplifier substantially equals the first bias voltage and such that a potential across the third switch substantially equals the offset voltage magnitude; and
the second amplifier is configured to drive the second cascode device such that a voltage at the input of the second amplifier substantially equals the second bias voltage and such that a potential across the fourth switch substantially equals the offset voltage magnitude.

6. The circuit of claim 5, wherein the third amplifier is configured to drive the third switch such that an on-resistance of the third switch matches an on-resistance of the fourth switch.

7. The circuit of claim 6, wherein the first voltage rail is configured to set the on-resistance of the fourth switch.

8. The circuit of claim 2, wherein the first voltage rail has a higher voltage than the second voltage rail, wherein the third switch comprises a p-channel metal-oxide semiconductor (PMOS) transistor, wherein the fourth switch comprises an n-channel metal-oxide semiconductor (NMOS) transistor, wherein the first cascode device comprises a PMOS transistor, and wherein the second cascode device comprises an NMOS transistor.

9. The circuit of claim 2, wherein the second voltage rail has a higher voltage than the first voltage rail, wherein the third switch comprises an n-channel metal-oxide semiconductor (NMOS) transistor, wherein the fourth switch comprises a p-channel metal-oxide semiconductor (PMOS) transistor, wherein the first cascode device comprises an NMOS transistor, and wherein the second cascode device comprises a PMOS transistor.

10. The circuit of claim 1, wherein at least one of the first amplifier or the second amplifier comprises a chopper-stabilized amplifier.

11. The circuit of claim 1, wherein at least one of the first amplifier or the second amplifier has an input offset voltage parameter of at most ±100 μV.

12. The circuit of claim 1, wherein the third amplifier is configured to control the third switch such that the voltage at the node equals the reference potential.

13. The circuit of claim 1, wherein the first switch and the second switch are part of a unit element in a resistive digital-to-analog converter (RDAC).

14. A method for setting a voltage level for controlling at least one of a first switch or a second switch, such that an on-resistance of the first switch matches an on-resistance of the second switch, the method comprising:
establishing a voltage magnitude across a third switch configured to replicate the first switch;
establishing the same voltage magnitude across a fourth switch configured to replicate the second switch;
setting an on-resistance of the fourth switch based on the voltage magnitude across the fourth switch;
comparing a voltage at a node between the third switch and the fourth switch with a reference potential; and
controlling the third switch based on the comparison such that an on-resistance of the third switch matches the on-resistance of the fourth switch, wherein an input of the third switch is configured to set the voltage level.

15. The method of claim 14, wherein the third switch is coupled to a first voltage rail and wherein the fourth switch is coupled to a second voltage rail.

16. The method of claim 15, wherein the setting comprises biasing the fourth switch with the first voltage rail.

17. The method of claim 15, wherein establishing the voltage magnitude across the third switch comprises:
driving a first cascode device with a first amplifier, wherein the first cascode device is connected in cascode with the third switch; and
biasing an input of the first amplifier with a first bias voltage, offset from the first voltage rail by the voltage magnitude, wherein another input of the first amplifier is coupled to the third switch and to the first cascode device and wherein the first cascode device is driven such that a voltage at the other input of the first amplifier substantially equals the first bias voltage.

18. The method of claim 17, wherein establishing the same voltage magnitude across the fourth switch comprises:
driving a second cascode device with a second amplifier, wherein the second cascode device is connected in cascode with the fourth switch; and
biasing an input of the second amplifier with a second bias voltage, offset from the second voltage rail by the same voltage magnitude, wherein another input of the second amplifier is coupled to the fourth switch and to the second cascode device and wherein the second cascode device is driven such that a voltage at the other input of the second amplifier substantially equals the second bias voltage.

19. The method of claim 15, wherein the first voltage rail has a higher voltage than the second voltage rail, wherein the third switch comprises a p-channel metal-oxide semiconductor (PMOS) transistor, and wherein the fourth switch comprises an n-channel metal-oxide semiconductor (NMOS) transistor.

20. The method of claim 15, wherein the second voltage rail has a higher voltage than the first voltage rail, wherein the third switch comprises an n-channel metal-oxide semiconductor (NMOS) transistor, and wherein the fourth switch comprises a p-channel metal-oxide semiconductor (PMOS) transistor.

21. The method of claim 14, wherein the comparing is performed via an amplifier, wherein the controlling comprises driving the third switch with the amplifier, and wherein an output of the amplifier is coupled to the input of the third switch.

22. An apparatus for setting a voltage level for controlling at least one of a first means for switching or a second means for switching, such that an on-resistance of the first means for switching matches an on-resistance of the second means for switching, the apparatus comprising:
means for establishing a voltage magnitude across a third means for switching configured to replicate the first means for switching;
means for establishing the same voltage magnitude across a fourth means for switching configured to replicate the second means for switching;
means for setting an on-resistance of the fourth means for switching based on the voltage magnitude across the fourth means for switching;
means for comparing a voltage at a node between the third means for switching and the fourth means for switching with a reference potential; and
means for controlling the third means for switching based on an output of the means for comparing such that an on-resistance of the third means for switching matches the on-resistance of the fourth means for switching, wherein an input of the third means for switching is configured to set the voltage level.

23. The apparatus of claim 22, wherein the third means for switching is coupled to a first means for providing power and wherein the fourth means for switching is coupled to a second means for providing power.

24. The apparatus of claim 23, wherein the means for setting is configured to bias the fourth means for switching with the first means for providing power.

25. The apparatus of claim 23, wherein the means for establishing the voltage magnitude across the third means for switching is configured to:
drive a first cascode device with a first amplifier, wherein the first cascode device is connected in cascode with the third means for switching; and
bias an input of the first amplifier with a first bias voltage, offset from the first means for providing power by the voltage magnitude, wherein another input of the first amplifier is coupled to the third means for switching and to the first cascode device and wherein the first cascode device is driven such that a voltage at the other input of the first amplifier substantially equals the first bias voltage.

26. The apparatus of claim 25, wherein the means for establishing the same voltage magnitude across the fourth means for switching is configured to:
drive a second cascode device with a second amplifier, wherein the second cascode device is connected in cascode with the fourth means for switching; and
bias an input of the second amplifier with a second bias voltage, offset from the second means for providing power by the same voltage magnitude, wherein another input of the second amplifier is coupled to the fourth means for switching and to the second cascode device and wherein the second cascode device is driven such that a voltage at the other input of the second amplifier substantially equals the second bias voltage.

27. The apparatus of claim 23, wherein the first means for providing power has a higher voltage than the second means for providing power, wherein the third means for switching comprises a p-channel metal-oxide semiconductor (PMOS) transistor, and wherein the fourth means for switching comprises an n-channel metal-oxide semiconductor (NMOS) transistor.

28. The apparatus of claim 23, wherein the second means for providing power has a higher voltage than the first means for providing power, wherein the third means for switching comprises an n-channel metal-oxide semiconductor (NMOS) transistor, and wherein the fourth means for switching comprises a p-channel metal-oxide semiconductor (PMOS) transistor.

29. The apparatus of claim 22, wherein the means for controlling is configured to drive the third means for switching with the means for comparing and wherein the output of the means for comparing is coupled to the input of the third means for switching.
